(19) United States
(12) Patent Application Publication
(10) Pub. No.: US 2016/0302335 A1
(43) Pub. Date: Oct. 13, 2016

(54) PRECISION MOUNTING SYSTEMS AND METHODS

(71) Applicant: Mettler-Toledo AutoChem, Inc., Columbia, MD (US)

(72) Inventor: Peter Alfred Blacklin, Columbia, MD (US)

(21) Appl. No.: 14/684,006

(22) Filed: Apr. 10, 2015

(51) Int. Cl. H05K 13/04

(52) U.S. Cl. CPC H05K 13/0413

(57) ABSTRACT

Systems and methods for precisely mounting components by means of pins secured within pin receiving holes by an adhesive. Prior to curing of the adhesive, the use of the pins and holes will generally permit an adjustment of the position/orientation of at least one component, as well as the alignment of one component to another, while the pins reside in the pin receiving holes. Systems and methods of the invention allow for highly precise alignment of components that is stable over a range of temperatures and through temperature changes, while negating any effects of adhesive shrinkage, and without imparting any axial pre-load or other distortions to the components.

### TECHNICAL FIELD

The invention is directed generally to the precision mounting and assembly of objects such as, but not limited to, optical components.

### BACKGROUND

Persons of skill in the art in a multitude of different technologies would recognize the need for the precision mounting and alignment of various components, such as optical components. During manufacturing operations, components may need to be precisely located, aligned, and mounted to some base structure, etc. In some cases, multiple components may need to be mounted to such a base structure and also precisely aligned with one another. Other scenarios are, of course, also possible.

When a component will be coupled to another structure in a known and fixed position, a number of alignment and affixation options are available. For example, the component to be installed and the structure that will receive the component may be provided with complimentary features that precisely align and locate the component. Alternatively, a component may be held in a precise position relative to another structure by a fixture, clamp or other mechanism until the component is completely affixed.

In any of the aforementioned scenarios, various techniques for affixing a component to another structure may be available. For example, when the initial location and orientation of a component can be assured, any number of affixation techniques may be employed, including the use of fasteners, adhesives, welding, etc. Clearly, the affixation technique selected will depend at least in art on the material forming the component and/or structure to which the component is to be mounted. Nonetheless, when a component is to be mounted to a structure in a location and orientation that need not be deliberately adjusted after the component is placed in contact with the structure, a wider variety of affixation techniques are available. Not all components may be mounted in such a fashion, however. For example, there are situations where one or more of the location and orientation of a component must be adjusted within a fine tolerance after being mated to the structure to which it will be mounted. In still other situations, multiple components must be very precisely aligned with one another while or after being mated to a receiving structure.

Not all components may be mounted in such a fashion, however. For example, there are situations where one or more of the location and orientation of a component must be adjusted within a fine tolerance after being mated to the structure to which it will be mounted. In still other situations, multiple components must be very precisely aligned with one another while or after being mated to a receiving structure.

Post-mating adjustments to a component that must be precision mounted complicates the mounting process and may reduce the number of affixation techniques available for use. For example, certain adhesives may not afford sufficient time for component adjustment prior to adhesive setup. An affixation technique such as welding may cause thermal changes that are sufficient to move the component from proper alignment as the weld area cools or to permanently distort the part or parts being affixed. The use of fasteners may impart an undesirable preload or distortion to a component.

One exemplary area of technology where the permanent precision mounting of device components is generally required is optics, and particularly interferometer optics. Various devices having optical components may require the precise mounting and alignment of those components such as light sources, lenses, mirrors, etc. More simplistic examples of optical devices may include, without limitation, binoculars, telescopes, and cameras, while more complex examples may include lasers, interferometers and spectrometers.

Many methods of supporting and moving the components of an optical device allow inadvertent motions of said components, thereby producing misalignment that may result in less than optimal device performance. This problem may be exacerbated in complex optical devices. For example, the misalignment of the optical components of an interferometer may result in non-ideal modulation, with resulting non-ideal and, generally, varying artifacts in the spectral output. Hence, it is desirable to provide precision mounting techniques that may be used to more easily and more precisely mount components such as optical elements in many different devices.

### SUMMARY

Exemplary embodiments of the invention generally are directed to the pre-attachment, precise alignment, and affixation of different types of components, particularly but not limited to, optical components. Exemplary embodiments of the invention enable inexpensive, compact and high quality production and also allow for the use of components made from a common material or from materials having substantially matching coefficients of thermal expansion, and for their affixation in permanent alignment to each other.

Exemplary embodiments of the invention, while not limited thereto, are ideally suited to the precision mounting of optical components such as but not limited to lasers and other light sources, lenses, mirrors, beam splitters, filters, prisms, polarizers, etc. Exemplary embodiments of the invention allow for such components to be initially aligned and then subsequently precisely adjusted and re-aligned prior to permanent affixation. Exemplary embodiments of the invention also minimize or eliminate any concerns that preload forces, applied mechanical forces, or conditions such as temperature changes will cause affixed components to subsequently become misaligned.

As generally mentioned above, non-limiting examples of optical-based devices to which embodiments of the invention may be applied may include devices with optical or optoelectronic components, such as binoculars, telescopes, cameras, lasers, interferometers and spectrometers. In the case of interferometers, for example, embodiments of the invention may be used to produce the required highly precise (e.g., 1 microradian deviation from incidence angle) reflector alignment, and can overcome known misalignment issues that may be caused by the temperature instability of typical interferometer mirror support mechanisms.

Exemplary embodiments of the invention are able to produce highly precise alignments and overcome such aforementioned problems by employing a combination of adhesive and pins, such as glass pins or pins having a coefficient of thermal expansion that is substantially the same as the material into which the pins will be installed. In one exemplary embodiment, one or more pin receiving holes are placed in a first component of interest as well as a structure or another component to which the first component will be affixed. The receiving holes are larger than the corresponding pin(s), and are of sufficient size to allow for adjustment of the component position on the receiving structure while the pin(s) reside within the receiving holes. In another exemplary embodiment, one or more pin receiving holes are placed in a first component or in a structure or other component to which the first component will be affixed, so as to again receive a pin and adhesive. In this exemplary embodiment, however, the pin(s) is either integral to or non-adjustably affixed to, whichever one of the components or structure it is that lacks a receiving hole(s). The receiving hole(s) is again larger than the pin(s), and is of sufficient size to allow for adjustment of the component position on the receiving structure while the pin(s) reside within the receiving hole(s).

The extra space (gap) between the pins and the surrounding walls of the holes in the component and mounting structure are filled with adhesive. Once the adhesive sets, the position of the component is permanently fixed. Various types of adhesives may be used. For example, the adhesive may be UV-curable, radiation (e.g., heat) curable, curable by solvent drying, or simply air curable. Alternatively, the adhesive may be in the form of a solder, a low-melting point glass, or a similar material, depending on the composition of the pins and the surrounding materials. Glass pins may be especially useful when the component is a mirror or lens, as glass pins will likely have a coefficient of thermal expansion that is the same as or similar to the material typically used to form the mirror or lens. Glass pins, or pins fabricated from other optically transparent materials, may also allow UV light or other radiant energy to pass therethrough, which is beneficial when an adhesive curable through the application of such energy is employed. UV-curing adhesives also may be used with metal components and metal pins by shining UV light into the annular space between the pin and the component.

It has been found that the use of mounting pins and curing adhesive around the pins, permits the alignment of components (such as interferometer mirrors) to microradian or better precision (when using appropriate and known holders). For example, when the component is a mirror of an interferometer or spectroscopic instrument, the angle of the mirror may be precisely adjusted to be aligned other components in the light path of the instrument while the pins are in place. Because the pins are surrounded in the receiving holes by adhesive, any negative effects of adhesive shrinkage are substantially reduced by symmetry. Furthermore, the pins impart no axial pre-load, which separates the use of such pins from the use of typical fasteners. Consequently, the use of such a mounting technique is simple, compact and inexpensive, while still allowing for highly precise component mounting and alignment that is stable across changing temperatures.

Other aspects and features of the invention will become apparent to those skilled in the art upon review of the following detailed description of exemplary embodiments along with the accompanying drawing figures.

### BRIEF DESCRIPTION OF THE DRAWINGS

In the following descriptions of the drawings and exemplary embodiments, like reference numerals across the several views refer to identical or equivalent features, and:

FIG. 1A is a sectional view of a portion of two components being secured to one another according to a mounting technique of the invention;

FIG. 1B is an enlarged detail view of a portion of FIG. 1A;

FIG. 1C is an enlarged end view of the component assembly of FIG. 1A;

FIG. 2 illustrates one exemplary embodiment of the component alignment adjustability afforded by systems and methods of the invention;

FIG. 3 is a sectional view of a portion of two components being secured to one another according to another exemplary mounting technique of the invention;

FIGS. 4A-4C depict one type of a known multi-axis optics mount to which exemplary system and method embodiments of the invention may be applied;

FIG. 5 schematically represents one version of a Michelson interferometer to which exemplary system and method embodiments of the invention may be applied;

FIGS. 6A-6B depict one exemplary corner reflector to which exemplary system and method embodiments of the invention may be applied;

FIG. 7 depicts one exemplary optoelectronic position sensor to which exemplary system and method embodiments of the invention may be applied;

FIG. 8 is a sectional view of a portion of two components being secured to one another according to yet another exemplary mounting technique of the invention; and

FIG. 9 is a sectional view of a portion of two components being secured to one another according to still another exemplary mounting technique of the invention.

### DETAILED DESCRIPTION OF EXEMPLARY EMBODIMENTS

System and method embodiments of the invention may be used to precisely mount a variety of components, where such components require precise and permanent alignment to one another or to a base structure. One non-limiting but applicable area of technology is optics and devices with optical or optoelectronic components.

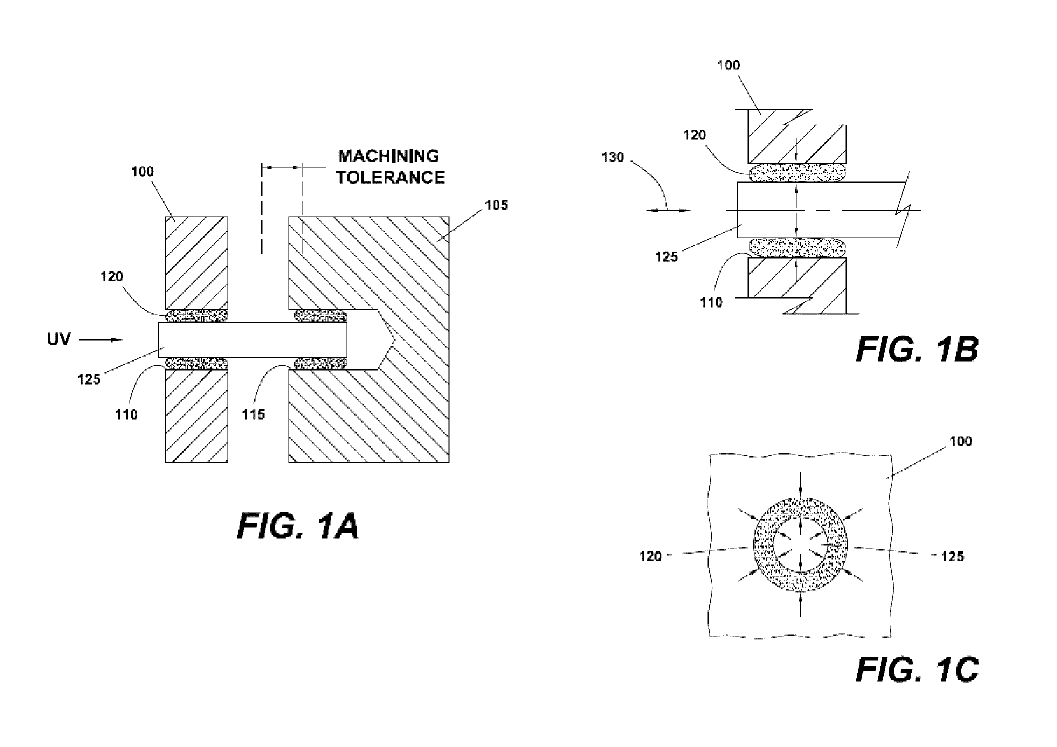

Referring to FIGS. 1A-3, various details of exemplary pin and adhesive mounting technique embodiments of the invention may be observed. As shown in FIG. 1A, a first component 100 and a second component 105 are affixed to one another using an exemplary pin and adhesive mounting technique of the invention. In this example, the first component 100 and second component 105 may reside on a common surface (e.g., base), or one of the components may be the base. As shown, each component 100, 105 includes a pin-receiving hole 110, 115. In this particular example, the pin-receiving hole 110 of the first component is a through-hole and the pin-receiving hole 115 of the second component is a bore that does not pass fully therethrough, although this certainly need not be the case in other embodiments.

The pin-receiving holes 110, 115 are of some size that is sufficient to receive both adhesive 120 and a pin 125. The difference between the internal dimension(s) of the holes 110, 115 and the external dimension(s) of the corresponding pin 125 may vary, depending for example on factors such as the particular adhesive used and the amount of component positional adjustment that might be required after initial assembly. In any case, the adhesive 120 fills the gap formed between the exterior surface of the pin 125 and the surrounding wall(s) of each hole 110, 115. It can also be readily observed in FIG. 1A how a pin and adhesive mounting technique according to the invention is unaffected by dimensional inconsistencies resulting from machining tolerances. Further, such a technique is very little affected by shrinkage on cure and thermal coefficient mismatch between the adhesive, or filled adhesive and the materials to be secured or affixed.

Referring now to FIGS. 1B-1C, further details associated with the exemplary pin and adhesive mounting of the components 100, 105 of FIG. 1A may be observed. While only a portion of the first component 100 and the pin 125 are shown in FIGS. 1B and 10, the following description would apply equally well to the second component 105 and that portion of the pin 125 residing therein. While FIGS. 1B and 10 depict the pin 125 being perfectly centered within the pin receiving hole 110, proper alignment and affixation of components maybe accomplished even with off-center pin placement.

As would be understood by one of skill in the art, the use of pins and adhesives as described herein eliminates misalignment problems related to the use of fasteners or other means of component securement that, by the nature of their operation, apply an undesirable pre-load and/or other deformation stress to the components affixed thereby. Similarly, the use of pins and adhesives as described herein eliminates misalignment problems related to deformation caused by unequal thermal expansion/contraction.

More particularly, and as represented by the corresponding arrow pairs of FIGS. 1B-1C, any radial forces and resulting stresses associated with curing of the adhesive 120 will not affect the position of the pin 125 within the holes 110 or the positional relationship between the components 100, 105 because such forces are resisted equally by the pin 125 and the components. Consequently, the position of the pin 125 within the holes 110, 115 will remain substantially the same as the adhesive 120 cures. It should be further noted that curing of the adhesive 120 applies no pre-load to the components 100, 105. That is, there is minimal force or resulting stress imparted by the adhesive in the axial direction of the pin 125 (as represented by the arrows 130 of FIG. 1B), nor is there any movement in this direction. Rather, any forces or stresses resulting from curing of the adhesive are radial in nature, as represented by the corresponding arrow pairs of FIGS. 1B and 1C.

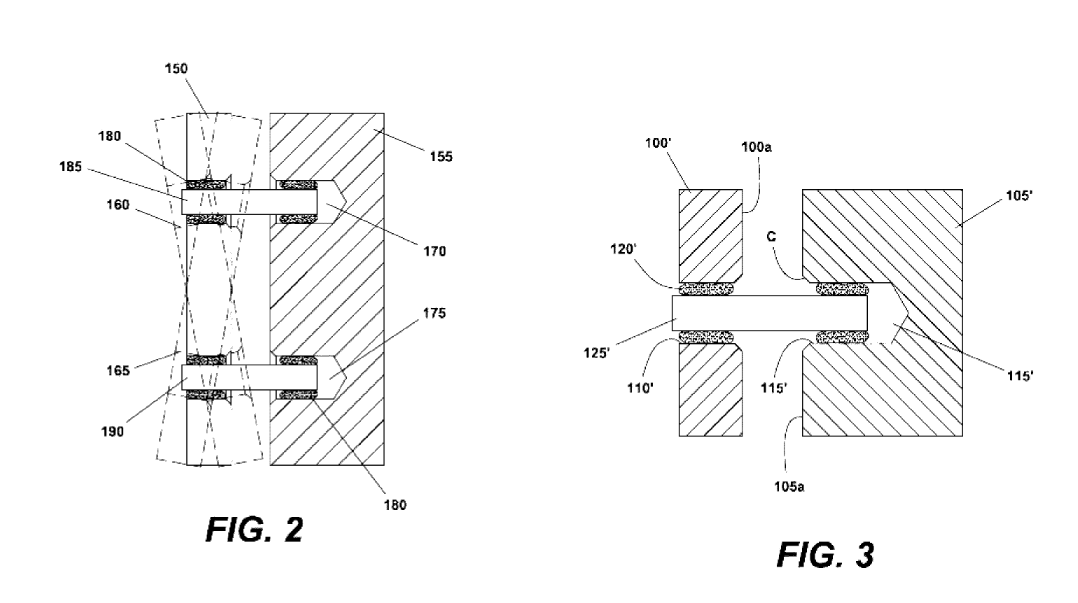

Referring now to FIG. 2, another pair of exemplary components 150, 155 is presented to demonstrate the positional adjustment of components that is afforded by systems and method embodiments of the invention. In this example, the two components 150, 155 are affixed to one another using pin and adhesive mounting technique similar to that of FIGS. 1A-1B, except that two pins are used.

As with the exemplary embodiment of FIGS. 1A-1C, the first component 150 and second component 155 of this embodiment may reside on a common surface (e.g., base), or one of the components may be the base. The first component 150 includes a pair of pin-receiving holes 160, 165, and the second component 155 includes a pair of pin-receiving holes 170, 175. In this particular example, the pin-receiving holes 160, 165 are again through-holes and the pin-receiving holes 170,175 of the second component are again bores that do not pass completely therethrough, although this certainly need not be the case in other embodiments. This aspect of the invention may be practiced equally well with through holes in both components, or blind holes in both components, or with any combination thereof.

Each receiving hole 160, 165 in at least the first component 150 is of a dimension that is sufficient to receive adhesive 180 and a respective pin 185, 190 while simultaneously allowing some amount of positional adjustment of the first component 150 with respect to the pins and to the second component 155 (as represented by the dashed line positions of the first component). The first component 150 may be aligned and adjusted along all three axes to the extent permitted by the clearance provided within the receiving holes 160, 165. The position of the second component 155 may or may not be adjustable about the pins 185, 190 in a similar manner. The difference between the internal dimension(s) of the receiving holes 160, 165 and the external dimension(s) of the corresponding pins 185, 190 may vary, depending for example on factors such as the particular adhesive used and the amount of component positional adjustment that may be required after initial assembly. In any case, the adhesive 180 again fills the gap formed between the exterior surface of the pins 185, 190 and the surrounding wall(s) of the holes 160, 165 in the first component 150 and the surrounding wall(s) of the holes 170, 175 in the second component 155. As with the example of FIGS. 1A-1C, curing of the adhesive 185 has no significant effect on the finally set position/orientation of the components 150, 155 of this embodiment.

FIG. 3 illustrates an alternative embodiment of the component assembly of FIG. 1A. In this embodiment, two components 100′, 105′ are again affixed to one another using an exemplary pin and adhesive mounting technique of the invention. Therefore, each component 100′, 105′ again includes a pin-receiving hole 110′, 115′ into which is inserted a pin 125′ and adhesive 120′. As would be understood by one of skill in the art, a weeping (e.g., oozing, dripping) of the adhesive 120′ onto the adjacent surfaces 100a, 105a of the components 100′, 105′ may be problematic, particularly if the adjacent component surfaces are in sufficiently close proximity such that weeped adhesive might cause the surfaces to be bonded together.

Consequently, in this embodiment, the receiving holes 110′, 115′ of the components 100′, 105′ are chamfered C at the adjacent surfaces 100a, 105a to collect any excess adhesive and to prevent any possible weeping of the adhesive 120′ onto the adjacent surfaces 100a, 105a.

An exemplary process of assembling components in a precisely aligned fashion according to exemplary mounting methods of the invention may generally involve several steps. For example, in an embodiment such as the exemplary embodiment of FIG. 2, wherein a first component and a second component are to be assembled to one another in precise permanent alignment, and wherein a plurality of pin receiving holes reside in each of the components, such steps may include: (1) initial assembly of the components (including mounting to a base structure if applicable); (2) insertion of the corresponding pins into the pin receiving holes of each component; (3) application of adhesive into the space between the pins and the receiving holes; (4) optional use of a precision positioning device(s) (which may be releasably connected to one or both components prior to or after adhesive application) to initially set the position of the components; (5) precise three-dimensional alignment of the components relative to one another and possibly relative to a base structure (whether by use of a precision positioning device(s) or otherwise); (6) curing of the adhesive (e.g., air, UV, radiation); and (7) removal of precision positioning device(s) if used. Once the adhesive has properly cured, the selected alignment of the components will be maintained. It should be observed that the steps above are intended to illustrate one possible exemplary assembly procedure; it is possible in embodiments of the invention to perform the steps in a different order (including but not limited to performing step 3 before step 2), to omit certain steps, or to perform additional steps beyond those in the exemplary method set forth.

Initial retention and alignment of any of the exemplary components of FIGS. 1A-3 may be accomplished with temporary fixtures, holders, etc., which would be familiar to one of skill in the art and are well known, for example, in the field of optics. Once the adhesive 120 sets, the temporary retention and alignment fixtures may be removed, whereby the precise position, orientation and alignment of the components, 100, 105 will be maintained by the adhesive.

Mounting components according to methods of the invention permits the precise location and alignment of said components. Particularly, mounting a component in such a manner allows the component to be adjusted as necessary to achieve proper location and/or alignment, after the component has been mated to the receiving structure and while the pin(s) and uncured adhesive reside within the corresponding receiving hole(s) of the component.

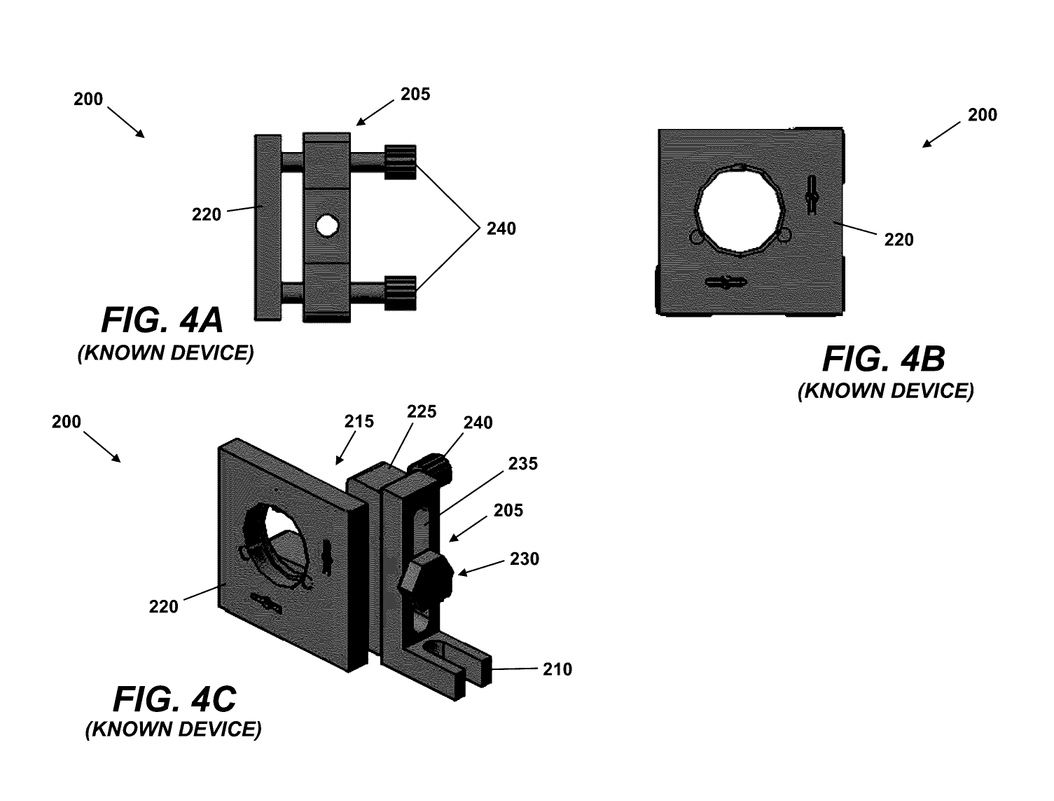

Referring now to FIG. 4, it may be understood how exemplary embodiments of the invention may be applied to a multi-axis optical holder, such as the illustrated and commercially available multiple-axis adjustable mirror or lens holder 200. As shown, the holder 200 includes a mounting element 205 having a base leg 210 adapted for attachment to a supporting structure such as a laser table or the base plate of an instrument. An optics mount, in this case a mirror or lens mount 215 is attached to the mounting element 205. The mount includes a retention plate 220 for the mirror or lens whose position and orientation is adjustable in all three dimensions with respect to the mounting element 205 and associated supporting structure to which the mounting element is attached. The retention plate 220 is movably secured to the mounting element 205 by a retention plate mounting arm 225. The vertical position of the retention plate 220 is retained by a threaded fastener assembly 230 that passes through a slot 235 in the mounting element 205 and into the retention plate mounting arm 225. The orientation of the retention plate 220 and its associated optical element may be adjusted and retained by adjusting screws 240.

Various components of the holder 200 may be replaced with pins and adhesive according to the invention in order to provide a permanent and precise alignment. For example, one or more holes may be placed in the retention plate mounting arm 225 to receive pins that pass through the slot 235 in the mounting element 205, with the pins secured in the holes and in the slot with adhesive. This would eliminate the need to permanently secure the vertical position of the optical element with the fastener assembly 230, and the associated alignment problems that may later result. Similarly, one or more corresponding holes may be placed in the retention plate 220 and the retention plate mounting arm 225 to receive pins that pass through corresponding holes and are secured therein with adhesive. This would eliminate the need to permanently fix the orientation of the optical element with the adjusting screws 240, and the associated alignment problems that may later result. Still further, the base leg 210 of the mounting element 205 may be affixed to a supporting structure with pins and adhesive, which would eliminate the need for threaded fasteners, welding, etc.

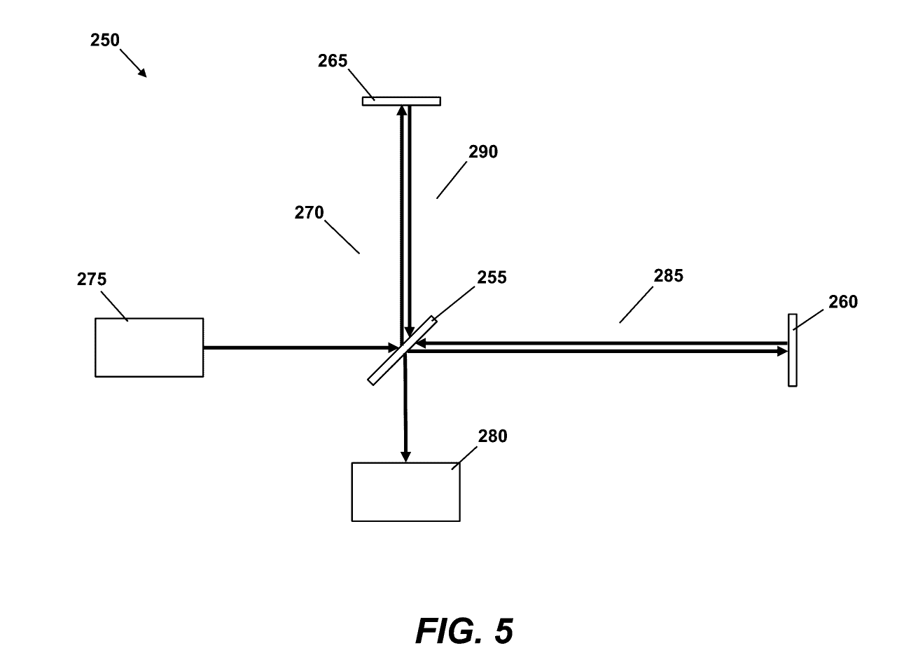

Referring now to FIG. 5, it may be understood how exemplary embodiments of the invention may be applied to an interferometer, such as the schematically illustrated Michelson interferometer 250. As shown, this exemplary Michelson interferometer 250 includes a series beam splitter 255, a first mirror 260, and a second mirror 265 arranged within a housing 270. A light source 275 (e.g., a laser) and a detector 280 are also present and may be arranged within the housing 270 as illustrated.

As would be well understood by one of skill in the art, the interferometer housing 270 defines two chambers 285, 290 of unequal length that are arranged at a ninety degree angle to one another. The beam splitter, which may include a compensator, is disposed at the intersection of the chambers 285, 290 and is oriented at a forty-five degree angle thereto. The two mirrors 260, 265 reside at the far end of respective ones of the chambers 285, 290 and, as such, are also arranged at a ninety degree angle to one another and at a forty-five degree angle to the beam splitter 255. As can be observed, the beam splitter is also oriented at a forty-five degree angle in relation to the incoming light beam from the light source 275.

In operation, a single light beam from the light source 275 is directed onto the beam splitter 255 where it is split into two beams. One beam is directed along a first path 285 at the first mirror 260 and the other beam is directed along a different path 290 at the second mirror 265, which may be a movable mirror. The light beams are reflected off of the first and second mirrors 260, 265 and returned to the beam splitter 255, where they are recombined and directed onto the detector 280. A collimator (not shown) may also reside in the path between the beam splitter 255 and the detector and/or in the path between the source 275 and the beam splitter 255.

Various components of the Michelson interferometer 250 may be permanently affixed using pins and adhesive according to embodiments of the invention. For example, each of the beam splitter 255 and/or the mirrors 260, 265 may be affixed to a surrounding mounting structure of the housing 270 and in proper, permanent, and precise alignment with each other using a pin and adhesive technique of the invention. This eliminates the need for elaborate and, in some cases, bulky mechanisms—such as a stack of materials including the glass mirror, an aluminum frame, and a steel screw in a brass nut—that are currently used to adjust the mirror angles and which suffer from thermal instability. Similarly, the light source 275 and/or the detector 280 may be affixed to a corresponding support structure using a pin and adhesive technique of the invention. The mounting structure or housing 270 and any employed collimators may also be so affixed.

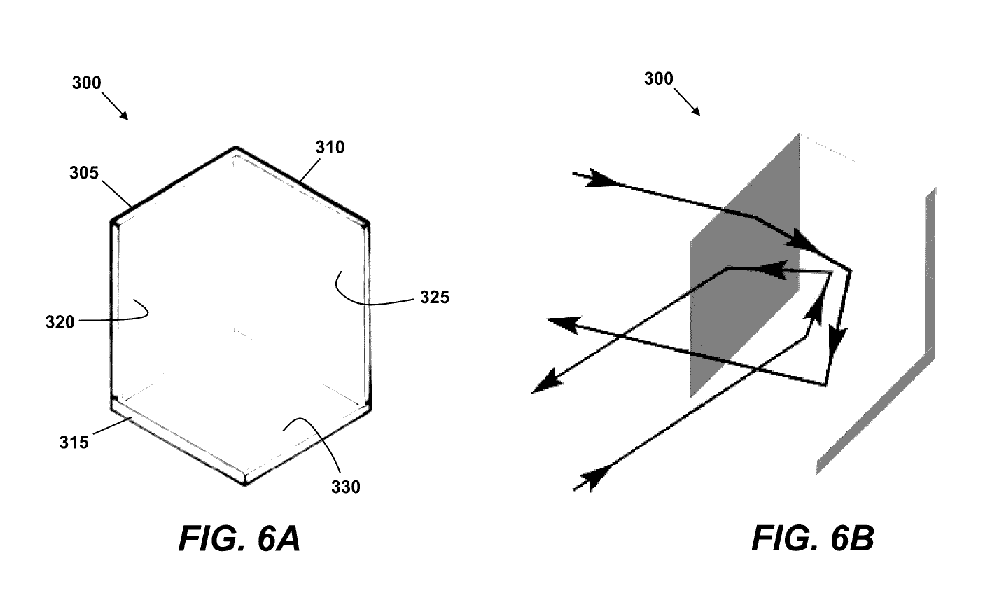

Referring now to FIGS. 6A-6B, it may be understood how exemplary embodiments of the invention may be applied to an optical corner cube retro-reflector, such as the schematically illustrated arrangement 300. As shown, the arrangement 300 includes three perpendicularly arranged walls 305, 310, 315 that generally form an open cube. To each of the inner faces of walls 305, 310, 315 is affixed a mirror 320, 325, 330 or otherwise reflective surface. Alternatively, the cooperating surfaces of the walls may be polished or otherwise caused to have a sufficiently reflective surface.

The orientation of the walls 305, 310, 315 must be precisely controlled such that light directed therefrom will be properly reflected as illustrated in FIG. 6B. Consequently, the walls 305, 310, 315 may be permanently affixed to one another in proper and precise alignment using pins and adhesive according to embodiments of the invention. Depending on their thickness, each of the mirrors 320, 325, 330 may also be affixed to the corresponding surfaces using pins and adhesive according to embodiments of the invention. Such use of pins and adhesive avoids the need for affixing the mirrors to the walls using fasteners or some type of framing structure that may impart preload stresses to the corner reflector 300 or may otherwise cause future misalignment due to thermal stresses.

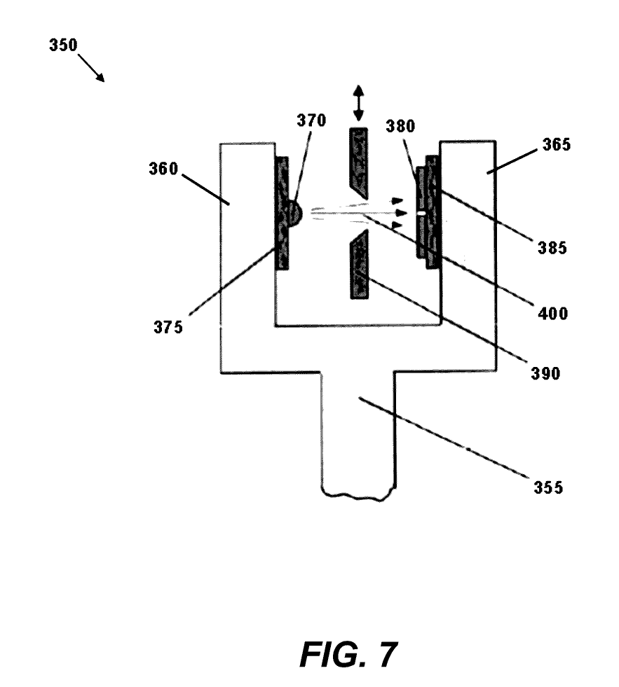

Referring now to FIG. 7, it can be understood how exemplary embodiments of the invention may be applied to an optoelectronic position sensor, such as for example the optoelectronic position sensor 350 described in US Patent Application No. 2013/0161103 A1. The optoelectronic position sensor 350 depicted in FIG. 7 is part of a weighing cell that includes a stationary base part 355 having an upwardly extending monolithic portion with two mounting surfaces 360, 365 that are separated by an interstitial space. A light emitter 370 is mounted on a first carrier element 375 that is affixed to one of the mounting surfaces 360. A light receiver 380 is mounted on a second carrier element 385 that is affixed to the other of the mounting surfaces 365 and aligned with the light emitter 370. A shutter vane 390 is attached to a lever of the weighing cell and is vertically displaceable (as indicated by the arrows 395) within the interstitial space and between the light emitter 370 and light receiver 380.

As would we understood by one of skill in the art, when the shutter 390 is displaced by loading of the weighing cell, the amount of light 400 flowing from the light emitter 370 to the light receiver 380 through a slit in the shutter vane 390 is influenced and a sensor signal is generated. This signal is sent to a closed-loop controller which, in response, regulates a compensation current in such a way that the resultant electromagnetic force acting between a coil and a permanent magnet of the weighing cell returns the shutter vane, the coil, and a balance beam and associated load receiver, to the zero position where the electromagnetic compensation force is in equilibrium with the weighing load. According to the laws of electromagnetism, the weight of the weighing load placed on the load receiver of the weighing cell can then be determined by measuring the coil current.

As would also be understood by one of skill in the art, weighing cells of this design are highly sensitive and may be capable of measuring a weighing load with an accuracy of, for example, one part in ten million. This accuracy is based in large part on the continual alignment of the light emitter 370 and light receiver 380, such that the only disturbance or change to the light beam impinging on the light receiver is caused by movement of the shutter vane.

With this in mind, it can be understood that employing pin and adhesive mounting techniques according to the invention to affix various components of the optoelectronic position sensor 350 may be very beneficial. For example, the light emitter 370 and light receiver 380 may be affixed to the mounting surfaces 360, 365 of the base part 355 using such pin and adhesive techniques. Alternatively, affixing the light emitter 370 and light receiver 380 with pins and adhesive according to the invention could eliminate concerns regarding thermal expansion of the mounting surfaces 360, 365 and, therefore, the monolithic construction of the base part 355 might be replaced with a simpler construction.

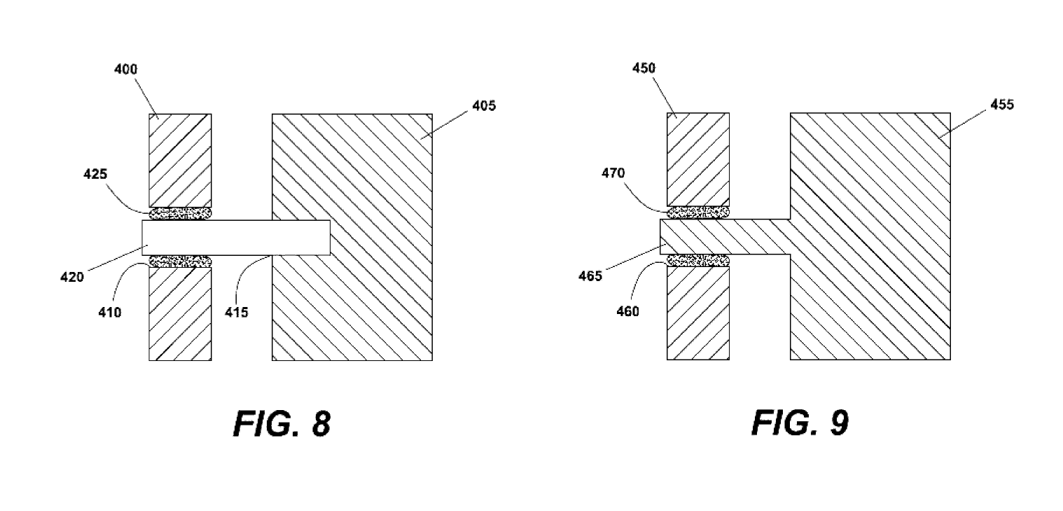

One alternative embodiment of an exemplary pin and adhesive mounting technique is illustrated in FIG. 8. As may be observed therein, a first component 400 and a second component 405 are again affixed to one another using an exemplary pin and adhesive mounting technique of the invention that is similar to, but slightly different from, the pin and adhesive mounting technique shown in FIG. 1A. The first component 400 and second component 405 may again reside on a common surface (e.g., base), or one of the components may be the base.

Each component 400, 405 again includes a pin-receiving hole 410, 415, with the pin-receiving hole 410 of the first component being a through-hole and the pin-receiving hole 415 of the second component being a bore that does not pass fully therethrough, although this certainly need not be the case in other similar embodiments. In this particular embodiment, however, only the pin-receiving hole 410 in the first component 400 is oversized to receive both a pin 420 and an adhesive 425 and to permit three-dimensional movement of the pin 420 within the hole 410 during component alignment as described above. In contrast, and unlike the embodiment depicted in FIG. 1A, the pin-receiving hole 415 in the second component of this embodiment is sized to tightly receive and retain the pin 420 with little to no movement. For example, and without limitation, the pin 420 may be press fit, glued, sonically welded or otherwise secured within the receiving hole 415 in the second component 405.

As with the previously-described exemplary embodiments, the difference between the internal dimension(s) of the pin receiving hole 410 in the first component 400 and the external dimension(s) of the corresponding pin 420 may vary, depending for example on factors such as the particular adhesive used and the amount of component positional adjustment that might be required after initial assembly. In any case, as with the previously-described embodiments, the adhesive 425 fills the gap formed between the exterior surface of the pin 420 and the surrounding wall(s) of the pin receiving hole 410 in the first component 400.

Another alternative embodiment of an exemplary pin and adhesive mounting technique is illustrated in FIG. 9. As may be observed therein, a first component 450 and a second component 455 are again affixed to one another using an exemplary pin and adhesive mounting technique of the invention that is similar to, but slightly different from, the pin and adhesive mounting technique shown in FIG. 8. The first component 450 and second component 455 may again reside on a common surface (e.g., base), or one of the components may be the base.

In this exemplary embodiment, only the first component 450 includes a pin-receiving hole 460. The pin-receiving hole 460 is again depicted as a through-hole, although this certainly need not be the case in other similar embodiments. The pin-receiving hole 460 in the first component 450 is once again oversized to receive both a pin 465 and an adhesive 470, and to permit three-dimensional movement of the pin 465 within the hole 470 during component alignment as described above.

Unlike the embodiments depicted in FIG. 1A and FIG. 8, the pin 465 of this embodiment is actually an integral, projecting portion of the second component 455. In other embodiments, the pin may of course be integral to the first component and the pin receiving hole and adhesive may be located in the second component.

As with the previously-described exemplary embodiments, the difference between the internal dimension(s) of the pin receiving hole 460 in the first component 455 and the external dimension(s) of the corresponding pin 465 may vary, depending for example on factors such as the particular adhesive used and the amount of component positional adjustment that might be required after initial assembly. In any case, as with the previously-described embodiments, the adhesive 470 fills the gap formed between the exterior surface of the pin 465 and the surrounding wall(s) of the pin receiving hole 460 in the first component 450.

Various types of adhesives may be used in exemplary system and method embodiments. For example, the adhesive may be UV-curable, radiation curable, or simply air curable. Examples of UV-curable adhesives include, without limitation, one-part liquid photopolymers such as Norland Optical Adhesive 61 and Norland Optical Adhesive 81, both of which are available from Norland Products in Cranbury, N.J. Highly-filled epoxies may also be used depending on the nature of the pins used. For Example, Hysol® epoxy resin (e.g., TRA-Bond 2151) available from Henkel North America in Rocky Hill, Conn. has been successfully used during testing in conjunction with aluminum pins. Alternatively, solder, low-melting point glass, a material curable by solvent drying, or a similar material, may be used as an adhesive depending on the composition of the pins and the surrounding materials.

As previously stated, glass pins may be used in embodiments of the invention. The glass used to construct the pins may vary, but one non-limiting example of a suitable glass pin material is lithium aluminum silicon oxide glass ceramic, such as the Zerodur® material available from Schott North America in Elmsford, N.Y. Glass pins may be especially useful from a thermal expansion standpoint when the component is an optical component, such as a lens or mirror. In an embodiment of the invention, glass pins may also allow UV light to pass therethrough, which is beneficial when a UV-curable adhesive is employed as UV light directed onto the pins can pass into the adhesive (see FIG. 1A). It is noted that the use of a UV-curable adhesive or other adhesives that do not cure simply by exposure to air, may permit additional time for adjustment of component location, alignment, etc. That is, using an adhesive that requires treatment other than just air exposure to cure eliminates the concern that the adhesive will set up prior to making all necessary positional adjustments to a given component. Pins constructed of other materials may also be used depending on the components being affixed and the particular application at hand. For example, aluminum, ceramic and carbon fiber pins may also be used. It may also be possible to employ highly-filled, long-strand fiber, plastic pins if the highly-filled plastic material thereof exhibits acceptable coefficient of thermal expansion characteristics.

The pins and pin-receiving holes utilized in various embodiments may be of different shapes and sizes. For example, the pins and corresponding pin-receiving holes used in other embodiments need not have the circular cross-section of the pins and pin-receiving holes of the exemplary embodiments described and shown herein. Rather, the pins and/or pin-receiving holes of other embodiments may have triangular, quadrilateral, etc., cross-sections, or may be hollow tubes that mate into annular spaces. The size of the pin(s) used for a given application may be selected based on, for example, the mass of the components being affixed, available space, anticipated shock loads, life loads, transportation loads etc. Depending on the nature of the component material(s) and/or the adhesive used, the material from which the pin(s) is manufactured may also be similarly selected.

In addition to permitting proper location, orientation, alignment, etc., of components, it is again noted that any negative effects of adhesive shrinkage are eliminated by system and method embodiments of the invention because the portions of the pins that reside in the pin-receiving holes are surrounded by adhesive. Furthermore, the use of pins and adhesive as explained herein imparts no axial pre-load, which separates the use of such pins and adhesive from the use of typical fasteners. Consequently, the use of such mounting techniques is simple, compact and inexpensive, while still allowing for highly precise component mounting and alignment that is stable across changing temperatures and for long periods of time, even in the presence of shock and vibration.

Furthermore, systems and methods according to the invention allow for reduced component machining costs because the necessary mounting precision is achieved in the final positioning of the components. Likewise, registration surfaces are not required to properly position a given component, nor is the use of a permanent clamp, clip, screw or other fastening element of a type that would place pressure on the element and possibly cause distortion (e.g., undesirable distortion of an optical element on a nanometer scale).

The use of systems and methods of the invention also results in low residual stresses on the associated components, and radial curing of the adhesive does not affect the position of the associated component, nor impart any through-part stresses. Similarly, any long term cure effects as well as any negative effects associated with adhesive creep may be significantly mitigated. Adhesive creep may also be minimized by the careful selection of the axial bonding length of the pin on each side, reducing any stresses due to the weight of the component. Alternatively, the number of pins may be increased to reduce the axial load on the adhesive. Thermal compatibility concerns also are eliminated by employing systems and methods of the invention, as thermal compatibility is retained in the positional mounting direction and the thermal compatibility of the adhesive is neutralized radially around the pin and within the adhesive length.

The use of a UV-cured adhesive or other non-time dependent curing materials also provides for an extended time period within which to adjust the position of a given component before curing of the adhesive is initiated. On the other hand, the use of time-dependent curing adhesives may allow for a better match of the coefficient of thermal expansion (CTE) of the materials involved. Thus, adhesive materials may be selected based on the given application and embodiments of the invention are not limited to the use of a particular adhesive or a particular type of adhesive.

While certain exemplary embodiments of the present invention are described in detail above, the scope of the invention is not to be considered limited by such disclosure, and modifications are possible without departing from the spirit of the invention as evidenced by the following claims:

What is claimed is:

1. A system for the precision mounting of components, comprising:
at least one pin-receiving hole located in a mounting surface of a first component to be mounted, and a corresponding number of pin-receiving holes located in a mounting surface of a second component to which the first component will be mounted, the pin-receiving hole(s) in the second component being aligned with the pin-receiving hole(s) in the first component so as to form one or more pin-receiving hole pairs;
a pin located partially in each pin-receiving hole of each pin-receiving hole pair in the first component and the second component; and
adhesive located in a gap formed between each pin and a surrounding walls of each pin-receiving hole;
wherein the gap between each pin and the surrounding wall of each pin-receiving hole is of sufficient dimension to permit adjustment of the aligned relationship of the components after assembly but prior to setting of the adhesive.

2. The system of claim 1, wherein at least the first component is an optical component.

3. The system of claim 2, wherein the optical component is selected from the group consisting of a mirror, light source, lens, beam splitter, filter, prism, and polarizer.

4. The system of claim 1, wherein both of the components are optical components.

5. The system of claim 1, wherein the pins are made of a glass material.

6. The system of claim 5, wherein the adhesive is UV-curable.

7. The system of claim 1, wherein the thermal coefficient of expansion of the adhesive substantially matches the thermal coefficient of expansion of the material from which at least the first component is manufactured.

8. The system of claim 7, wherein the adhesive is selected from the group consisting of a UV-curable material, an air-curable material, a radiation-curable material, solder, and low-melting point glass.

9. The system of claim 1, wherein the adhesive is selected from the group consisting of a UV-curable material, an air curable material, a radiation-curable material, solder, and low-melting point glass.

10. The system of claim 1, wherein the pin receiving holes along the mounting surface of each component are chamfered to prevent weeping of the adhesive.

11. The system of claim 1, further comprising a component alignment fixture for temporarily holding and maintaining the first component in a properly aligned position with the second component while the adhesive cures.

12. A method for precisely mounting components, comprising:
placing at least one pin-receiving hole in a mounting surface of a first component to be mounted;
placing a corresponding number of pin-receiving holes in a mounting surface of a second component to which the first component will be mounted, the pin-receiving hole(s) in the second component being aligned with the pin-receiving hole(s) in the first component so as to form one or more pin-receiving hole pairs;
locating a portion of a common pin within each pin-receiving hole of each pin-receiving hole pair in the first component and the second component;
filling a gap between each pin and a surrounding wall of the corresponding pin-receiving hole with adhesive; and
adjusting the aligned relationship of the components after assembly thereof but prior to setting of the adhesive.

13. The method of claim 12, wherein at least the first component is an optical component.

14. The method of claim 13, wherein the optical component is selected from the group consisting of a mirror, light source, lens, beam splitter, filter, prism, and polarizer.

15. The method of claim 12, wherein the pins are made of a glass material.

16. The method of claim 15, wherein the adhesive is UV-curable.

17. The method of claim 12, wherein the thermal coefficient of expansion of the adhesive substantially matches the thermal coefficient of expansion of the material from which at least the first component is manufactured.

18. The method of claim 12, wherein the adhesive is selected from the group consisting of a UV-curable material, an air curable material, a radiation-curable material, solder, and low-melting point glass.

19. The method of claim 12, further comprising chamfering the pin receiving holes along the mounting surface of each component to prevent weeping of the adhesive.

20. The method of claim 12, further comprising providing a component alignment fixture and using the fixture to temporarily hold and maintain the first component in a properly aligned position relative to the second component while the adhesive sets.

21. A system for the precision mounting of components, comprising:
a pin-receiving hole located in a mounting surface of a first component to be mounted, and a corresponding pin-receiving hole located in a mounting surface of a second component to which the first component will be mounted, the pin-receiving hole in the second component being aligned with the pin-receiving hole in the first component so as to form a pin-receiving hole pair;
a pin located partially in each pin-receiving hole of each pin-receiving hole pair in the first component and the second component; and
adhesive located in a gap formed between a surrounding wall of at least one of the pin-receiving holes and that portion of the pin residing therein;
wherein the gap is of sufficient dimension to permit adjustment of the aligned relationship of the components after assembly but prior to setting of the adhesive.

22. The system of claim 21, wherein at least one of the components is an optical component selected from the group consisting of a mirror, light source, lens, beam splitter, filter, prism, and polarizer.

23. The system of claim 1, wherein the pin is made of a glass material.

24. The system of claim 23, wherein the adhesive is UV-curable.

25. The system of claim 21, wherein the thermal coefficient of expansion of the adhesive substantially matches the thermal coefficient of expansion of the material from which at least one of the components is manufactured.

26. The system of claim 1, wherein the adhesive is selected from the group consisting of a UV-curable material, an air curable material, a radiation-curable material, solder, and low-melting point glass.

27. The system of claim 21, further comprising a component alignment fixture for temporarily holding and maintaining the first component in a properly aligned position with the second component while the adhesive cures.

28. A system for the precision mounting of components, comprising:
a pin-receiving hole located in a mounting surface of a first component to be mounted;
a pin formed as an integral part of a second component to which the first component will be mounted, the pin of the second component being located at least partially within the pin-receiving hole of the first component; and
adhesive located in a gap formed between a surrounding wall of the pin-receiving hole in the first component and that portion of the pin of the second component residing therein;
wherein the gap is of sufficient dimension to permit adjustment of the aligned relationship of the components after assembly but prior to setting of the adhesive.

29. The system of claim 28, wherein at least one of the components is an optical component selected from the group consisting of a mirror, light source, lens, beam splitter, filter, prism, and polarizer.

30. The system of claim 31, wherein the second component and its pin are made of a glass material.

31. The system of claim 30, wherein the adhesive is UV-curable.

32. The system of claim 28, wherein the thermal coefficient of expansion of the adhesive substantially matches the thermal coefficient of expansion of the material from which at least one of the components is manufactured.

33. The system of claim 28, wherein the adhesive is selected from the group consisting of a UV-curable material, an air curable material, a radiation-curable material, solder, and low-melting point glass.

34. The system of claim 28, further comprising a component alignment fixture for temporarily holding and maintaining the first component in a properly aligned position with the second component while the adhesive cures.
